(19) United States
(12) Patent Application Publication
(10) Pub. No.: US 2026/0006795 A1
(43) Pub. Date: Jan. 1, 2026

(54) APPARATUS AND METHODS FOR REDUCING NEAR-NEAR - FAR-FAR MEMORY CELL RESISTANCE DIFFERENCES IN MEMORY ARRAYS

(71) Applicant: Sandisk Technologies, Inc., Milpitas, CA (US)

(72) Inventors: Kadriye Deniz Bozdag, Sunnyvale, CA (US); Mark Lin, Santa Clara, CA (US); Christopher J. Petti, Mountain View, CA (US)

(73) Assignee: Sandisk Technologies, Inc., Milpitas, CA (US)

(21) Appl. No.: 18/756,676

(22) Filed: Jun. 27, 2024

(51) Int. Cl. H10B 61/00

(52) U.S. Cl. CPC H10B 61/10

(57) ABSTRACT

An apparatus includes a first memory cell coupled between a first word line and a first bit line and series coupled with a first word line resistance and first bit line resistance, and a second memory cell coupled between a second word line and a second bit line and series coupled with a second word line resistance and second bit line resistance. The first memory cell includes a first hard mask including a first hard mask material having a first resistivity, and the second memory cell includes a second hard mask including a second hard mask material having a second resistivity lower than the first resistivity. The first hard mask is configured to compensate for a difference between a first sum of the first word line resistance and the first bit line resistance and a second sum of the second word line resistance and the second bit line resistance.

### BACKGROUND

Memory is widely used in various electronic devices such as cellular telephones, digital cameras, personal digital assistants, medical electronics, mobile computing devices, non-mobile computing devices and data servers. Memory may be non-volatile memory or volatile memory. A non-volatile memory allows information to be stored and retained even when the non-volatile memory is not connected to a source of power (e.g., a battery).

One example of a non-volatile memory is magnetoresistive random access memory (MRAM), which uses magnetization to represent stored data, in contrast to some other memory technologies that store data using electronic charge. Generally, MRAM includes a large number of magnetic memory cells formed on a semiconductor substrate, where each memory cell represents one bit of data.

A data bit is written to a memory cell by changing the direction of magnetization of a magnetic element within the memory cell, and a bit is read by measuring the resistance of the memory cell (low resistance typically represents a “0” bit, and high resistance typically represents a “1” bit). As used herein, direction of magnetization is the direction of orientation of the magnetic moment. Some memory cells may include a selector device, such as an ovonic threshold switch or other selector device.

Although MRAM is a promising technology, numerous design and process challenges remain.

### BRIEF DESCRIPTION OF THE DRAWINGS

FIGS. 1A-1H depict various embodiments of a memory system.

FIG. 2A depicts an embodiment of a portion of a three-dimensional memory array.

FIG. 2B depicts an embodiment of a memory cell of the three-dimensional memory array of FIG. 2A.

FIG. 2C depicts an example current-voltage characteristic of a threshold selector device of FIG. 2B.

FIGS. 3A-3B depict an embodiment of a cross-point memory array.

FIG. 4A is a top-level view of memory block.

FIG. 4B is a top-level view of a memory array of the memory block of FIG. 4A.

FIG. 4C depicts a simplified model of the memory array of FIG. 4B including word line resistances and bit line resistances.

FIG. 5A is a simplified perspective view of a memory block.

FIG. 5B is a simplified perspective view of an embodiment of memory cells a memory array of the memory block of FIG. 5A.

FIG. 5C is a simplified cross-sectional view during an example fabrication of the memory cells of FIG. 5B.

FIG. 5D is a simplified cross-sectional view during an alternative example fabrication of the memory cells of FIG. 5B.

FIG. 5E is a flow diagram of a simplified process for forming a memory array such as the portion of a memory array depicted in FIG. 5D.

FIG. 5F is a simplified cross-sectional view during another alternative example fabrication of the memory cells of FIG. 5B.

FIG. 5G is a simplified cross-sectional view during yet another alternative example fabrication of the memory cells of FIG. 5B.

FIG. 6 is a flow diagram of an embodiment of a method for forming a memory array, such as the memory array of the memory block of FIG. 5A.

### DETAILED DESCRIPTION

One type of memory array includes multiple word lines, multiple bit lines, and memory cells that include a magnetic memory element coupled in series with a selector element disposed at the intersections of each word line and each bit line. The word lines are coupled to a word line driver circuit, and the bit lines are coupled to a bit line driver circuit. Because of the array geometry, some of the memory cells are located close to the word line driver circuit and the bit line driver circuit, whereas others of the memory cells are located far from the word line driver circuit and the bit line driver circuit.

As a result of resistance in the word lines and the bit lines, a resistance difference exists between memory cells located close to the word line and bit line driver circuits and the memory cells located far from the word line and bit line driver circuit. The resistance difference can create may problems during operation of the memory array. Among other problems, memory cells located close to the word line and bit line driver circuits experience higher read disturb and endurance problems compared to memory cells located far from the word line and bit line driver circuit.

Technology is described to reduce the resistance difference between memory cells located close to the word line and bit line driver circuits and the memory cells located far from the word line and bit line driver circuit. In embodiments, an additional resistance is coupled to and/or incorporated in memory cells located close to the word line and bit line driver circuits. In embodiments, the additional resistance substantially equals the resistance difference between memory cells located close to the word line and bit line driver circuits and the memory cells located far from the word line and bit line driver circuit.

In embodiments, the memory cells include a memory element coupled in series with a selector device. In an embodiment, the memory element is a magnetic memory element. In an embodiment, the memory element is a magnetic tunnel junction memory element. In an embodiment, the selector device is an ovonic threshold switch.

In an embodiment, memory cells within a memory array may include non-volatile memory cells including a reversible resistance-switching element. A reversible resistance-switching element may include a reversible resistivity-switching material having a resistivity that may be reversibly switched between two or more states.

In an embodiment, the reversible resistance-switching material may include a metal oxide, solid electrolyte, phase-change material, magnetic material, or other similar resistivity-switching material. Various metal oxides can be used, such as transition metal-oxides. Examples of metal-oxides include, but are not limited to, NiO, Nb₂O₅, TiO₂, HfO₂, Al₂O₃, MgOₓ, CrO₂, VO, BN, TaO₂, Ta₂O₃, and AlN.

In an embodiment, non-volatile memory cells within a memory array include one-time programmable memory cells. In an embodiment, non-volatile memory cells within a memory array include re-writeable memory cells.

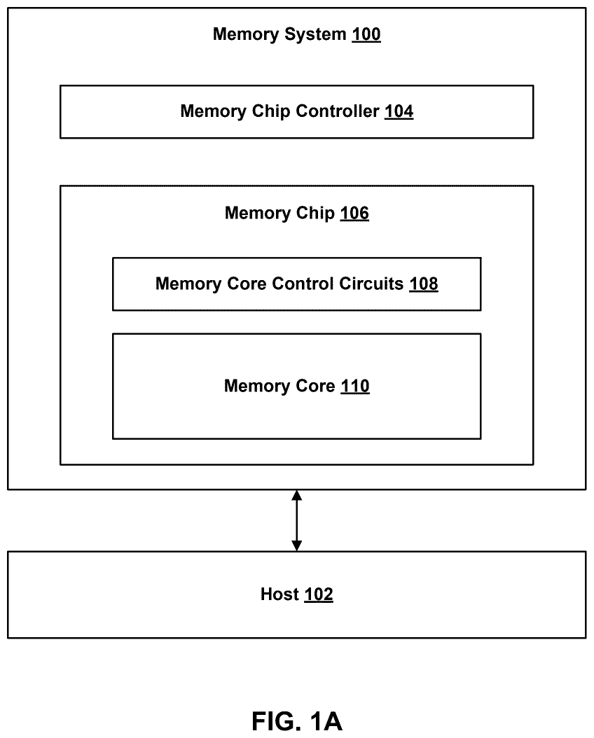

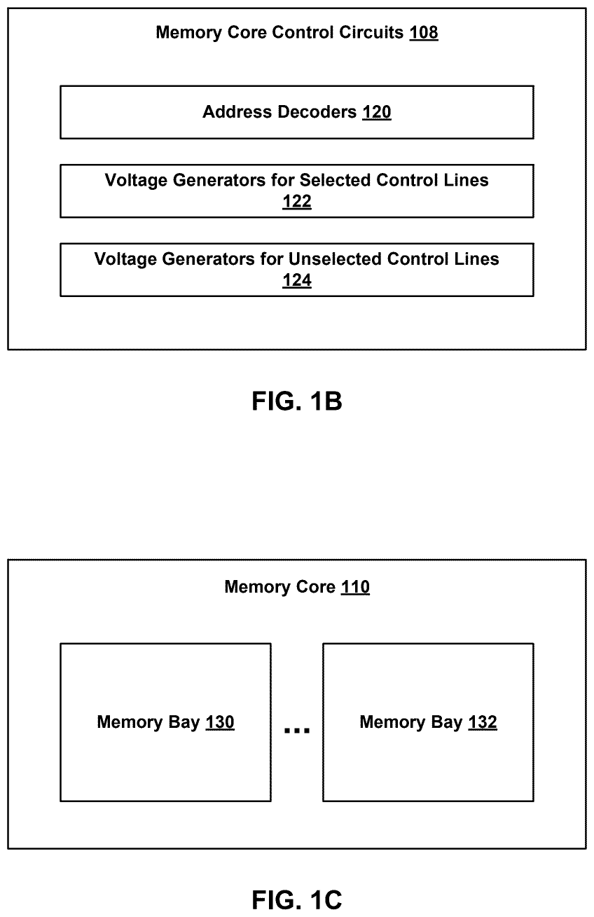

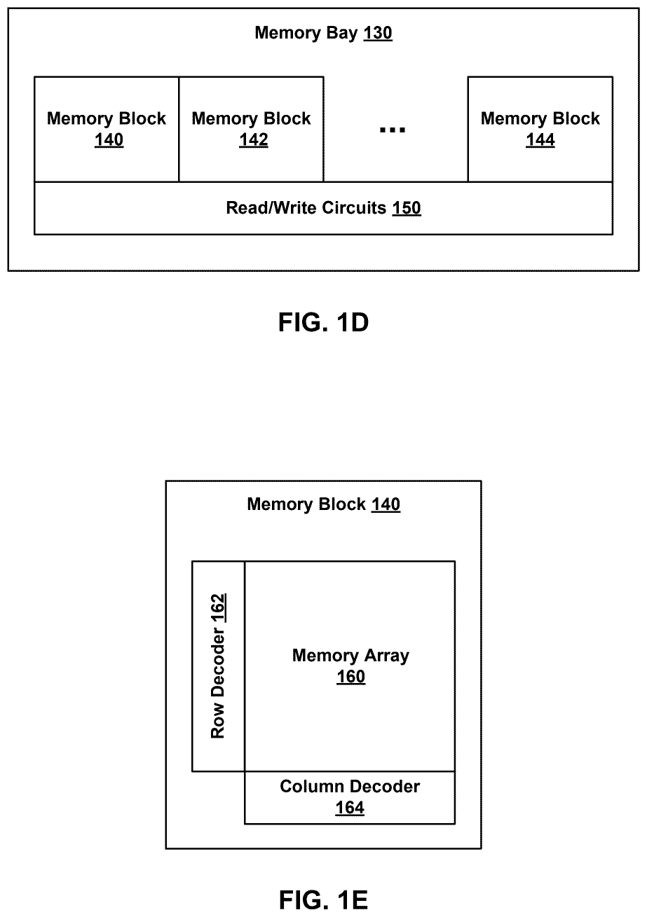

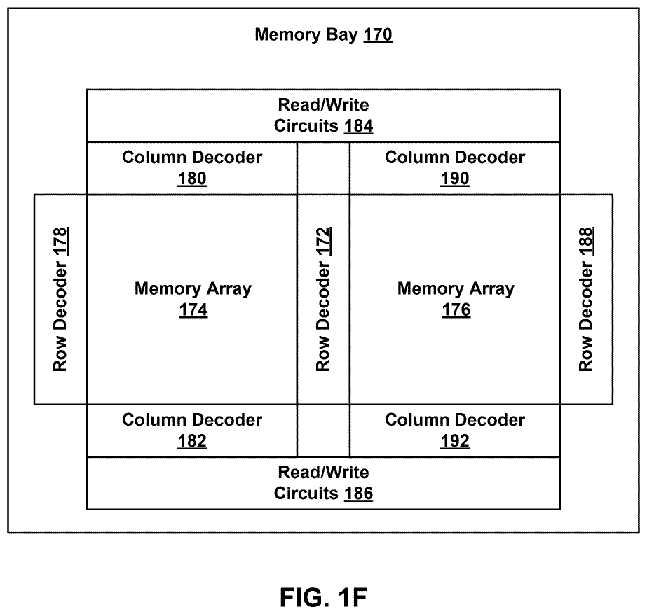

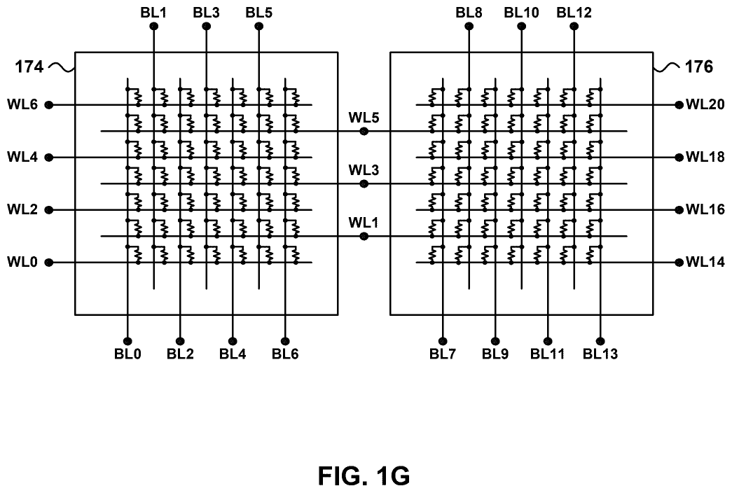

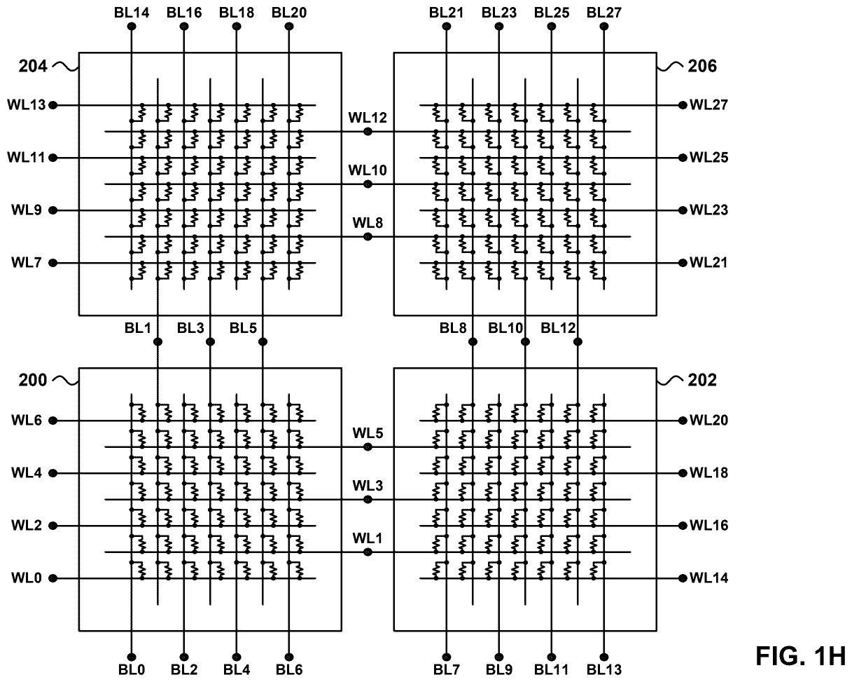

FIG. 1A depicts one embodiment of a memory system 100 and a host 102. Memory system 100 may include a non-volatile storage system interfacing with host 102 (e.g., a mobile computing device or a server). In some cases, memory system 100 may be embedded within host 102. As examples, memory system 100 may be a memory card, a solid-state drive (SSD) such a high density MLC SSD (e.g., 2-bits/cell or 3-bits/cell) or a high performance SLC SSD, or a hybrid HDD/SSD drive.

As depicted, memory system 100 includes a memory chip controller 104 and a memory chip 106. Memory chip 106 may include volatile memory and/or non-volatile memory. Although a single memory chip is depicted, memory system 100 may include more than one memory chip. Memory chip controller 104 may receive data and commands from host 102 and provide memory chip data to host 102.

Memory chip controller 104 may include one or more of control circuitry, state machines, page registers, SRAM, decoders, sense amplifiers, read/write circuits, and/or controllers, or any combination thereof, for controlling the operation of memory chip 106. The one or more control circuitry, state machines, page registers, SRAM, decoders, sense amplifiers, read/write circuits, and/or controllers for controlling the operation of the memory chip may be referred to as managing or control circuits. The managing or control circuits may facilitate one or more memory array operations including forming, erasing, programming, or reading operations.

In some embodiments, the managing or control circuits (or a portion of the managing or control circuits) for facilitating one or more memory array operations may be integrated within memory chip 106. Memory chip controller 104 and memory chip 106 may be arranged on a single integrated circuit or arranged on a single die. In other embodiments, memory chip controller 104 and memory chip 106 may be arranged on different integrated circuits. In some cases, memory chip controller 104 and memory chip 106 may be integrated on a system board, logic board, or a PCB.

Memory chip 106 includes memory core control circuits 108 and a memory core 110. Memory core control circuits 108 may include logic for controlling the selection of memory blocks (or arrays) within memory core 110, controlling the generation of voltage references for biasing a particular memory array into a read or write state, and generating row and column addresses.

Memory core 110 may include one or more two-dimensional arrays of memory cells and/or one or more three-dimensional arrays of memory cells. In an embodiment, memory core may include re-writable memory cells, one-time programmable memory cells, and/or multi-time programmable memory cells, or any combination thereof.

In an embodiment, memory core control circuits 108 and memory core 110 may be arranged on a single integrated circuit. In other embodiments, memory core control circuits 108 (or a portion of memory core control circuits 108) and memory core 110 may be arranged on different integrated circuits.

A memory operation may be initiated when host 102 sends instructions to memory chip controller 104 indicating that host 102 would like to read data from memory system 100 or write data to memory system 100. In the event of a write (or programming) operation, host 102 may send to memory chip controller 104 both a write command and the data to be written.

Memory chip controller 104 may buffer data to be written and may generate error correction code (ECC) data corresponding with the data to be written. The ECC data, which allows data errors that occur during transmission or storage to be detected and/or corrected, may be written to memory core 110 or stored in non-volatile memory within memory chip controller 104. In an embodiment, the ECC data are generated and data errors are corrected by circuitry within memory chip controller 104.

Memory chip controller 104 may control operation of memory chip 106. In an example, before issuing a write operation to memory chip 106, memory chip controller 104 may check a status register to make sure that memory chip 106 is able to accept the data to be written.

In another example, before issuing a read operation to memory chip 106, memory chip controller 104 may pre-read overhead information associated with the data to be read. The overhead information may include ECC data associated with the data to be read or a redirection pointer to a new memory location within memory chip 106 in which to read the data requested.

Once memory chip controller 104 initiates a read or write operation, memory core control circuits 108 may generate appropriate bias voltages and/or currents for word lines and bit lines within memory core 110, as well as generate the appropriate memory block, row, and column addresses.

FIG. 1B depicts an embodiment of memory core control circuits 108. In an embodiment, memory core control circuits 108 include address decoders 120, voltage generators for selected control lines 122, and voltage generators for unselected control lines 124. Control lines may include word lines, bit lines, or a combination of word lines and bit lines. Selected control lines may include selected word lines or selected bit lines that are used to place memory cells into a selected state. Unselected control lines may include unselected word lines or unselected bit lines that are used to place memory cells into an unselected state.

Voltage generators (or voltage regulators) for selected control lines 122 may include one or more voltage generators for generating selected control line voltages. Voltage generators for unselected control lines 124 may include one or more voltage generators for generating unselected control line voltages. Address decoders 120 may generate memory block addresses, as well as row addresses and column addresses for a particular memory block.

FIGS. 1C-1F depict one embodiment of a memory core organization that includes a memory core 110 having multiple memory bays, and each memory bay having multiple memory blocks. Although a memory core organization is disclosed where memory bays include memory blocks, and memory blocks include a group of memory cells, other organizations or groupings also can be used with the technology described herein.

FIG. 1C depicts an embodiment of memory core 110 of FIG. 1A. As depicted, memory core 110 includes memory bay 130 and memory bay 132. In some embodiments, the number of memory bays per memory core can be different for different implementations. For example, a memory core may include only a single memory bay or multiple memory bays (e.g., 16 memory bays, 256 memory bays, etc.).

FIG. 1D depicts one embodiment of memory bay 130 of FIG. 1C. As depicted, memory bay 130 includes memory blocks 140-144 and read/write circuits 150. In some embodiments, the number of memory blocks per memory bay may be different for different implementations. For example, a memory bay may include one or more memory blocks (e.g., 32 memory blocks per memory bay).

Read/write circuits 150 include circuitry for reading and writing memory cells within memory blocks 140-144. As depicted, read/write circuits 150 may be shared across multiple memory blocks within a memory bay. This allows chip area to be reduced because a single group of read/write circuits 150 may be used to support multiple memory blocks. However, in some embodiments, only a single memory block may be electrically coupled to read/write circuits 150 at a particular time to avoid signal conflicts.

In some embodiments, read/write circuits 150 may be used to write one or more pages of data into memory blocks 140-144 (or into a subset of the memory blocks). The memory cells within memory blocks 140-144 may permit direct over-writing of pages (i.e., data representing a page or a portion of a page may be written into memory blocks 140-144 without requiring an erase or reset operation to be performed on the memory cells prior to writing the data).

In an example, memory system 100 of FIG. 1A may receive a write command including a target address and a set of data to be written to the target address. Memory system 100 may perform a read-before-write (RBW) operation to read the data currently stored at the target address before performing a write operation to write the set of data to the target address. Memory system 100 may then determine whether a particular memory cell may stay at its current state (i.e., the memory cell is already at the correct state), needs to be set to a “0” state, or needs to be reset to a “1” state.

Memory system 100 may then write a first subset of the memory cells to the “0” state and then write a second subset of the memory cells to the “1” state. The memory cells that are already at the correct state may be skipped over, thereby improving programming speed and reducing the cumulative voltage stress applied to unselected memory cells.

A particular memory cell may be set to the “1” state by applying a first voltage difference across the particular memory cell of a first polarity (e.g., +1.5V). The particular memory cell may be reset to the “0” state by applying a second voltage difference across the particular memory cell of a second polarity that is opposite to that of the first polarity (e.g., −1.5V).

In some cases, read/write circuits 150 may be used to program a particular memory cell to be in one of three or more data/resistance states (i.e., the particular memory cell may comprise a multi-level memory cell). In an example, read/write circuits 150 may apply a first voltage difference (e.g., 2V) across the particular memory cell to program the particular memory cell to a first state of the three or more data/resistance states, or a second voltage difference (e.g., 1V) across the particular memory cell that is less than the first voltage difference to program the particular memory cell to a second state of the three or more data/resistance states.

Applying a smaller voltage difference across the particular memory cell may cause the particular memory cell to be partially programmed or programmed at a slower rate than when applying a larger voltage difference. In another example, read/write circuits 150 may apply a first voltage difference across the particular memory cell for a first time period (e.g., 150 ns) to program the particular memory cell to a first state of the three or more data/resistance states, or apply the first voltage difference across the particular memory cell for a second time period less than the first time period (e.g., 50 ns). One or more programming pulses followed by a memory cell verification phase may be used to program the particular memory cell to be in the correct state.

FIG. 1E depicts one embodiment of memory block 140 of FIG. 1D. As depicted, memory block 140 includes a memory array 160, a row decoder 162, and a column decoder 164. Memory array 160 may include a contiguous group of memory cells having contiguous word lines and bit lines. Memory array 160 may include one or more layers of memory cells, and may include a two-dimensional memory array and/or a three-dimensional memory array.

Row decoder 162 decodes a row address and selects a particular word line in memory array 160 when appropriate (e.g., when reading or writing memory cells in memory array 160). Column decoder 164 decodes a column address and selects a particular group of bit lines in memory array 160 to be electrically coupled to read/write circuits, such as read/write circuits 150 of FIG. 1D. In an embodiment, the number of word lines is 4K per memory layer, the number of bit lines is 1K per memory layer, and the number of memory layers is 4, providing a memory array 160 containing 16M memory cells. Other numbers of word lines per layer, bit lines per layer, and number of layers may be used.

FIG. 1F depicts an embodiment of a memory bay 170. Memory bay 170 is an example of an alternative implementation for memory bay 130 of FIG. 1D. In some embodiments, row decoders, column decoders, and read/write circuits may be split or shared between memory arrays. As depicted, row decoder 172 is shared between memory arrays 174 and 176, because row decoder 172 controls word lines in both memory arrays 174 and 176 (i.e., the word lines driven by row decoder 172 are shared).

Row decoders 178 and 172 may be split such that even word lines in memory array 174 are driven by row decoder 178 and odd word lines in memory array 174 are driven by row decoder 172. Column decoders 180 and 182 may be split such that even bit lines in memory array 174 are controlled by column decoder 182 and odd bit lines in memory array 174 are driven by column decoder 180.

The selected bit lines controlled by column decoder 180 may be electrically coupled to read/write circuits 184. The selected bit lines controlled by column decoder 182 may be electrically coupled to read/write circuits 186. Splitting the read/write circuits into read/write circuits 184 and 186 when the column decoders are split may allow for a more efficient layout of the memory bay.

Row decoders 188 and 172 may be split such that even word lines in memory array 176 are driven by row decoder 188 and odd word lines in memory array 176 are driven by row decoder 172. Column decoders 190 and 192 may be split such that even bit lines in memory array 176 are controlled by column decoder 192 and odd bit lines in memory array 176 are driven by column decoder 190.

The selected bit lines controlled by column decoder 190 may be electrically coupled to read/write circuits 184. The selected bit lines controlled by column decoder 192 may be electrically coupled to read/write circuits 186. Splitting the read/write circuits into read/write circuits 184 and 186 when the column decoders are split may allow for a more efficient layout of the memory bay.

FIG. 1G depicts an embodiment of a schematic diagram (including word lines and bit lines) corresponding with memory bay 170 in FIG. 1F. As depicted, word lines WL1, WL3, and WL5 are shared between memory arrays 174 and 176 and controlled by row decoder 172 of FIG. 1F. Word lines WL0, WL2, WL4, and WL6 are driven from the left side of memory array 174 and controlled by row decoder 178 of FIG. 1F. Word lines WL14, WL16, WL18, and WL20 are driven from the right side of memory array 176 and controlled by row decoder 188 of FIG. 1F.

Bit lines BL0, BL2, BL4, and BL6 are driven from the bottom of memory array 174 and controlled by column decoder 182 of FIG. 1F. Bit lines BL1, BL3, and BL5 are driven from the top of memory array 174 and controlled by column decoder 180 of FIG. 1F. Bit lines BL7, BL9, BL11, and BL13 are driven from the bottom of memory array 176 and controlled by column decoder 192 of FIG. 1F. Bit lines BL8, BL10, and BL12 are driven from the top of memory array 176 and controlled by column decoder 190 of FIG. 1F.

In an embodiment, memory arrays 174 and 176 may include memory layers that are oriented in a plane that is horizontal to the supporting substrate. In another embodiment, memory arrays 174 and 176 may include memory layers that are oriented in a plane that is vertical with respect to the supporting substrate (i.e., the vertical plane is substantially perpendicular to the supporting substrate). In this case, the bit lines of the memory arrays may include substantially vertical bit lines.

FIG. 1H depicts one embodiment of a schematic diagram (including word lines and bit lines) corresponding with a memory bay arrangement wherein word lines and bit lines are shared across memory blocks, and both row decoders and column decoders are split. Sharing word lines and/or bit lines helps to reduce layout area because a single row decoder and/or column decoder can be used to support two memory arrays.

As depicted, word lines WL1, WL3, and WL5 are shared between memory arrays 200 and 202. Bit lines BL1, BL3, and BL5 are shared between memory arrays 200 and 204. Word lines WL8, WL10, and WL12 are shared between memory arrays 204 and 206. Bit lines BL8, BL10, and BL12 are shared between memory arrays 202 and 206.

Row decoders are split such that word lines WL0, WL2, WL4, and WL6 are driven from the left side of memory array 200 and word lines WL1, WL3, and WL5 are driven from the right side of memory array 200. Likewise, word lines WL7, WL9, WL11, and WL13 are driven from the left side of memory array 204 and word lines WL8, WL10, and WL12 are driven from the right side of memory array 204.

Column decoders are split such that bit lines BL0, BL2, BL4, and BL6 are driven from the bottom of memory array 200 and bit lines BL1, BL3, and BL5 are driven from the top of memory array 200. Likewise, bit lines BL7, BL9, BL11, and BL13 are driven from the bottom of memory array 202 and bit lines BL8, BL10, and BL12 are driven from the top of memory array 202. Splitting row and/or column decoders also helps to relieve layout constraints (e.g., the column decoder pitch can be relieved by 2× since the split column decoders need only drive every other bit line instead of every bit line).

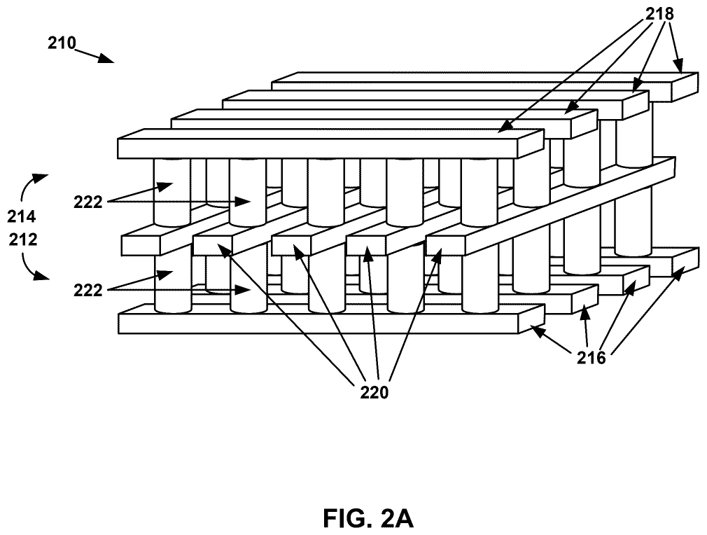

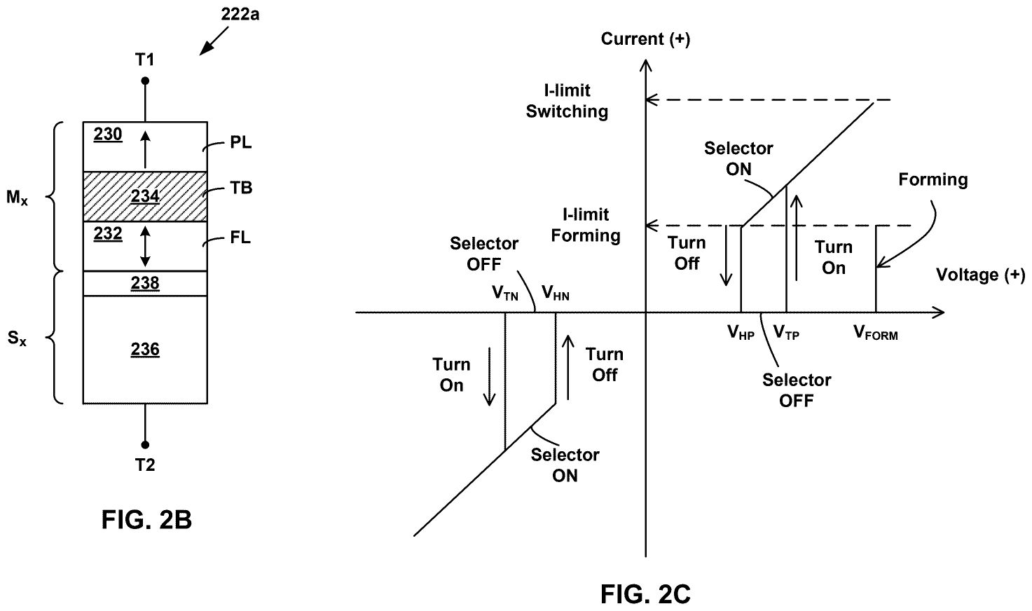

FIG. 2A depicts an embodiment of a portion of a monolithic three-dimensional memory array 210 that includes a first memory level 212, and a second memory level 214 positioned above first memory level 212. Memory array 210 is an example of an implementation of memory array 160 in FIG. 1E. Word lines 216 and 218 are arranged in a first direction and bit lines 220 are arranged in a second direction perpendicular to the first direction. As depicted, the upper conductors of first memory level 212 may be used as the lower conductors of second memory level 214. In a memory array with additional layers of memory cells, there would be corresponding additional layers of bit lines and word lines.

Memory array 210 includes memory cells 222. In embodiments, memory cells 222 may include re-writeable memory cells, one-time programmable memory cells, and multi-time programmable memory cells. In an embodiment, each of memory cells 222 are vertically-oriented. Memory cells 222 may include non-volatile memory cells or volatile memory cells. With respect to first memory level 212, a first portion of memory cells 222 are between and connect to word lines 216 and bit lines 220. With respect to second memory level 214, a second portion of memory cells 222 are between and connect to word lines 218 and bit lines 220.

In an embodiment, each memory cell 222 includes a selector element coupled in series with a resistance-switching memory element, where each memory cell 222 represents one bit of data. In an embodiment, the resistance-switching memory element may be a magnetic memory element, a ReRAM memory element, a phase change memory element or other type of resistance-switching memory element.

In an embodiment, each memory cell 222 includes a selector element coupled in series with a magnetic memory element, where each memory cell 222 represents one bit of data. FIG. 2B is a simplified schematic diagram of a memory cell 222a, which is one example implementation of memory cells 222 of FIG. 2A.

In an embodiment, memory cell 222a includes a magnetic memory element Mₓ coupled in series with a selector element Sₓ, both coupled between a first terminal T1 and a second terminal T2. In an embodiment, memory cell 222a is vertically-oriented. In the embodiment of FIG. 2B, magnetic memory element Mₓ is disposed above selector element Sₓ. In other embodiments, selector element Sₓ may be disposed above magnetic memory element Mₓ.

In an embodiment, magnetic memory element Mₓ is a magnetic tunnel junction, and selector element Sₓ is a threshold selector device. In an embodiment, selector element Sₓ is a conductive bridge threshold selector device. In other embodiments, selector element Sₓ is an ovonic threshold switch (e.g., binary SiTe, CTe, BTe, AlTe, etc., or the ternary type AsTeSi, AsTeGe or AsTeGeSiN, etc.), a Metal Insulator Transition (MIT) of a Phase Transition Material type (e.g., VO₂, NbO₂ etc.), or other similar threshold selector device.

In an embodiment, magnetic memory element Mₓ includes an upper ferromagnetic layer 230, a lower ferromagnetic layer 232, and a tunnel barrier (TB) 234 which is an insulating layer between the two ferromagnetic layers. In this example, lower ferromagnetic layer 232 is a free layer (FL) that has a direction of magnetization that can be switched. Upper ferromagnetic layer 230 is the pinned (or fixed) layer (PL) that has a direction of magnetization that is not easily changed.

In other embodiments, magnetic memory element Mₓ may include fewer, additional, or different layers than those depicted in FIG. 2B. In other embodiments, lower ferromagnetic layer 232 is a pinned layer (PL) and upper ferromagnetic layer 230 is the free layer (FL).

When the direction of magnetization in free layer 232 is parallel to that of pinned layer 230, memory element Mₓ has a relatively low resistance (referred to herein as the “P state”), and when the direction of magnetization in free layer 232 is anti-parallel to that of pinned layer 230, memory element Mₓ has a relatively high resistance (referred to herein as the “AP state”).

In an embodiment, the data state (“0” or “1”) of magnetic memory element Mₓ is read by measuring the resistance of magnetic memory element Mₓ. By design, both the parallel and anti-parallel configurations remain stable in the quiescent state and/or during a read operation (at sufficiently low read current).

In an embodiment, selector element Sₓ is an ovonic threshold switch that includes a first region 236 and optionally includes a second region 238 disposed above first region 236. In an embodiment, first region 236 is a SiTe alloy, and optional second region 238 is carbon nitride. Other materials may be used for first region 236 and optional second region 238. In other embodiments, selector element Sₓ is a conductive bridge threshold selector element. In an embodiment, first region 236 is a solid electrolyte region, and second region 238 is an ion source region.

FIG. 2C is a diagram depicting example current-voltage (I-V) characteristics of a threshold selector device Sₓ. Each threshold selector device Sₓ is initially in a high resistance (OFF) state. To operate threshold selector device Sₓ as a threshold switch, an initial forming operation may be necessary so that threshold selector device Sₓ operates in a current range in which switching can occur.

For example, a forming operation may include applying to threshold selector device Sₓ one or more voltage pulses each having a magnitude greater than or equal to a forming voltage V_{FORM}. Following the forming operation, threshold selector device Sₓ may be switched ON and OFF, and may be used as either a unipolar or a bipolar threshold selector device. Accordingly, threshold selector device Sₓ may be referred to as a bipolar threshold selector device.

In the example I-V characteristics of FIG. 2C, for positive applied voltages, threshold selector device Sₓ remains in a high resistance state (HRS) (e.g., OFF) until the voltage across the device meets or exceeds (i.e., is more positive than) a first threshold voltage, V_{TP}, at which point threshold selector device Sₓ switches to a low resistance state (LRS) (e.g., ON). Threshold selector device Sₓ remains turned ON until the voltage across the device drops to or below a first hold voltage, V_{HP}, at which point threshold selector device 224 turns OFF.

For negative applied voltages, threshold selector device Sₓ remains in a HRS (e.g., OFF) until the voltage across the device meets or exceeds (i.e., is more negative than) a second threshold voltage, V_{TN}, at which point threshold selector device 304 switches to a LRS (e.g., ON). Threshold selector device Sₓ remains turned ON until the voltage across the device increases to or exceeds (i.e., is less negative than) a second hold voltage, V_{HN}, at which point threshold selector device Sₓ turns OFF.

Referring again to FIG. 2B, in an embodiment, magnetic memory element Mₓ uses spin-transfer-torque (STT) switching. To “set” a bit value of magnetic memory element Mₓ (i.e., choose the direction of the free layer magnetization), an electrical write current is applied from first terminal T1 to second terminal T2. The electrons in the write current become spin-polarized as they pass through pinned layer 230 because pinned layer 230 is a ferromagnetic metal.

A substantial majority of the conduction electrons in a ferromagnet will have a spin orientation that is parallel to the direction of magnetization, yielding a net spin polarized current. (Electron spin refers to angular momentum, which is directly proportional to but anti-parallel in direction to the magnetic moment of the electron, but this directional distinction will not be used going forward for ease of discussion.)

When the spin-polarized electrons tunnel across TB 234, conservation of angular momentum can result in the imparting of a torque on both free layer 232 and pinned layer 230, but this torque is inadequate (by design) to affect the direction of magnetization of pinned layer 230. Contrastingly, this torque is (by design) sufficient to switch the direction of magnetization of free layer 232 to become parallel to that of pinned layer 230 if the initial direction of magnetization of free layer 232 was anti-parallel to pinned layer 230. The parallel magnetizations will then remain stable before and after such write current is turned OFF.

In contrast, if free layer 232 and pinned layer 230 magnetizations are initially parallel, the direction of magnetization of free layer 232 can be STT-switched to become anti-parallel to that of pinned layer 230 by applying a write current of opposite direction to the aforementioned case. Thus, by way of the same STT physics, the direction of the magnetization of free-layer 232 can be deterministically set into either of two stable orientations by judicious choice of the write current direction (polarity).

In the example described above, spin-transfer-torque (STT) switching is used to “set” a bit value of magnetic memory element Mₓ. In other embodiments, field-induced switching, spin orbit torque (SOT) switching, VCMA (magnetoelectric) switching, or other switching techniques may be employed.

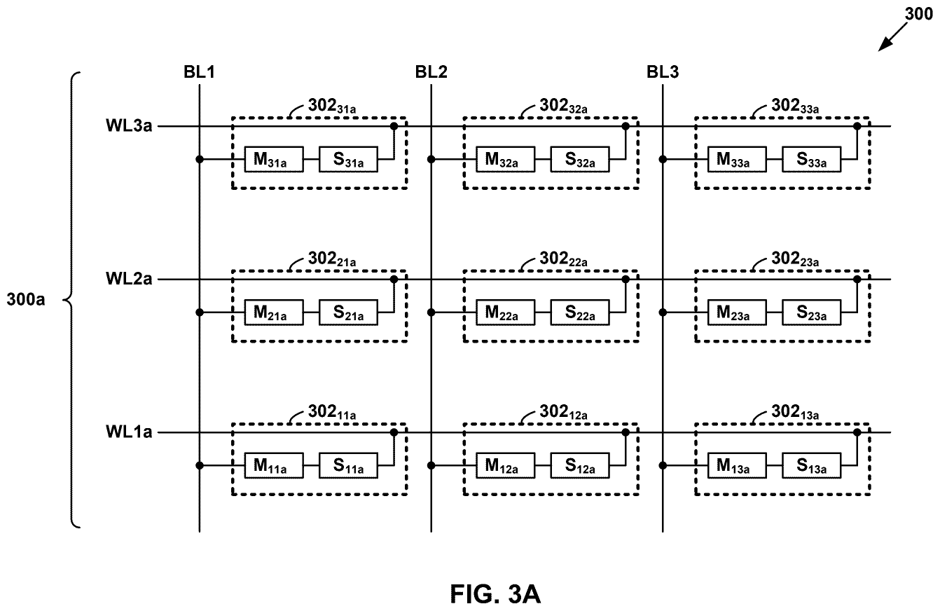

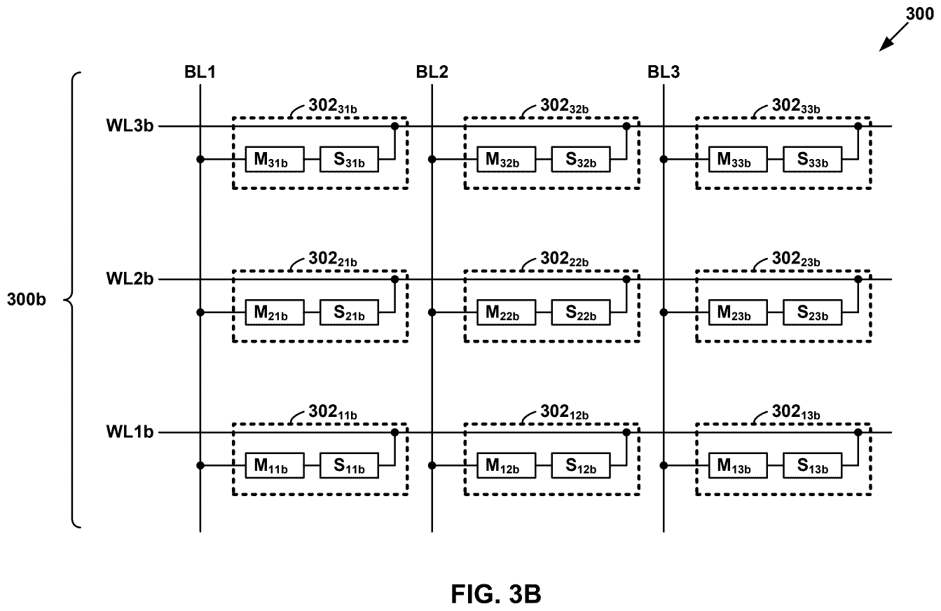

FIGS. 3A-3B are simplified schematic diagrams of an example cross-point memory array 300 which includes a first memory level 300a, and a second memory level 300b positioned above first memory level 300a. Cross-point memory array 300 is an example of an implementation of memory array 160 in FIG. 1E. Cross-point memory array 300 may include more than two memory levels.

Cross-point memory array 300 includes word lines WL1a, WL2a, WL3a, WL1b, WL2b, and WL3b, and bit lines BL1, BL2, and BL3. First memory level 300a includes memory cells 302₁₁ₐ, 302₁₂ₐ, . . . , 302₃₃ₐ coupled to word lines WL1a, WL2a, WL3a and bit lines BL1, BL2, and BL3, and second memory level 300b includes memory cells 302_{11b}, 302_{12b}, . . . , 302_{33b} coupled to word lines WL1b, WL2b, WL3b and bit lines BL1, BL2, and BL3. In an embodiment, each of memory cells 302₁₁ₐ, 302₁₂ₐ, . . . , 302₃₃ₐ are vertically-oriented. In an embodiment, each of memory cells 302_{11b}, 302_{12b}, . . . , 302_{33b} are vertically-oriented.

First memory level 300a is one example of an implementation for first memory level 212 of monolithic three-dimensional memory array 210 of FIG. 2A, and second memory level 300b is one example of an implementation for second memory level 214 of monolithic three-dimensional memory array 210 of FIG. 2A. In an embodiment, each of memory cells 302₁₁ₐ, 302₁₂ₐ, . . . , 302₃₃ₐ, 302_{11b}, 302_{12b}, . . . , 302_{33b}, is an implementation of memory cell 222a of FIG. 2B.

Persons of ordinary skill in the art will understand that cross-point memory array 300 may include more or less than six word lines, more or less than three bit lines, and more or less than eighteen memory cells 302₁₁ₐ, 302₁₂ₐ, . . . , 302₃₃ₐ, 302_{11b}, 302_{12b}, . . . , 302_{33b}. In some embodiments, cross-point memory array 300 may include 1000×1000 memory cells, although other array sizes may be used.

Each memory cell 302₁₁ₐ, 302₁₂ₐ, . . . , 302₃₃ₐ, 302_{11b}, 302_{12b}, . . . , 302_{33b} is coupled to one of the word lines and one of the bit lines, and includes a corresponding magnetic memory element M₁₁ₐ, M₁₂ₐ, . . . , M₃₃ₐ, M_{11b}, M_{12b}, . . . , M_{33b}, respectively, coupled in series with a corresponding selector element S₁₁ₐ, S₁₂ₐ, . . . , S₃₃ₐ, S_{11b}, S_{12b}, . . . , S_{33b}, respectively. In an embodiment, each of magnetic memory elements M₁₁ₐ, M₁₂ₐ, . . . , M₃₃ₐ, M_{11b}, M_{12b}, . . . , M_{33b} is an implementation of magnetic memory element Mₓ of FIG. 2B, and each of selector elements S₁₁ₐ, S₁₂ₐ, . . . , S₃₃ₐ, S_{11b}, S_{12b}, . . . , S_{33b} is an implementation of selector element Sₓ of FIG. 2B.

Each memory cell 302₁₁ₐ, 302₁₂ₐ, . . . , 302₃₃ₐ has a first terminal coupled to one of bit lines BL1, BL2, BL3, and a second terminal coupled to one of word lines WL1a, WL2a, WL3a, and each memory cell 302_{11b}, 302_{12b}, . . . , 302_{33b} has a first terminal coupled to one of bit lines BL1, BL2, BL3, and a second terminal coupled to one of word lines WL1b, WL2b, WL3b. For example, memory cell 302₁₃ₐ includes magnetic memory element M₁₃ₐ coupled in series with selector element S₁₃ₐ, and includes a first terminal coupled to bit line BL3, and a second terminal coupled to word line WL1a.

Likewise, memory cell 302_{22b} includes magnetic memory element M_{22b} coupled in series with selector element S_{22b}, and includes a first terminal coupled to bit line BL2, and a second terminal coupled to word line WL2b. Similarly, memory cell 302₃₃ₐ includes magnetic memory element M₃₃ₐ coupled in series with selector element S₃₃ₐ, and includes a first terminal coupled to bit line BL3, and a second terminal coupled to word line WL3a.

Magnetic memory elements M₁₁ₐ, M₁₂ₐ, . . . , M₃₃ₐ may be disposed above or below corresponding selector elements S₁₁ₐ, S₁₂ₐ, . . . , S₃₃ₐ, respectively, and magnetic memory elements M_{11b}, M_{12b}, . . . , M_{33b}, may be disposed above or below corresponding selector elements S_{11b}, S_{12b}, . . . , S_{33b}, respectively.

In an embodiment, the orientation of memory cells 302₁₁ₐ, 302₁₂ₐ, . . . , 302₃₃ₐ of first memory level 300a is the same as the orientation of memory cell 302_{11b}, 302_{12b}, . . . , 302_{33b} of second memory level 300b.

In another embodiment, the orientation of memory cells 302₁₁ₐ, 302₁₂ₐ, . . . , 302₃₃ₐ of first memory level 300a is opposite the orientation of memory cell 302_{11b}, 302_{12b}, . . . , 302_{33b} of second memory level 300b.

Referring again to FIG. 1A, in an embodiment memory core 110 may include one or more two-dimensional arrays of memory cells and/or one or more three-dimensional arrays of memory cells. In an embodiment, memory core 110 may include re-writable memory cells, one-time programmable memory cells, and/or multi-time programmable memory cells, or any combination thereof.

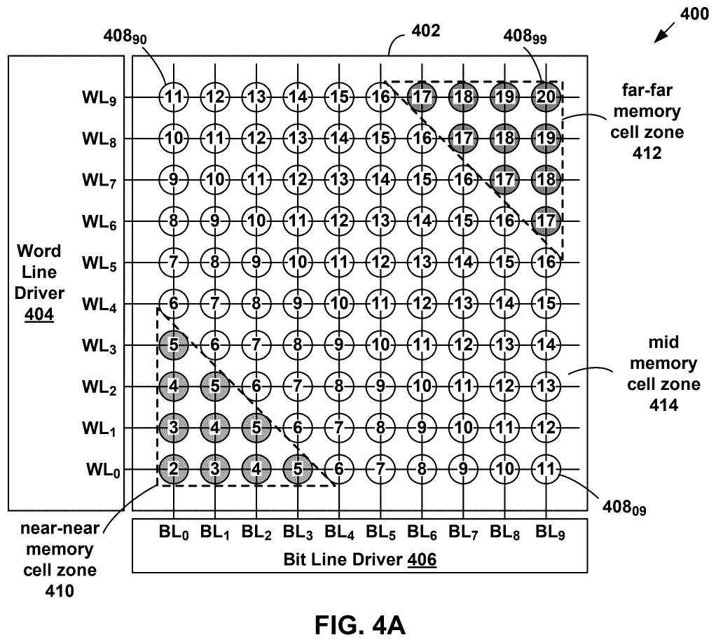

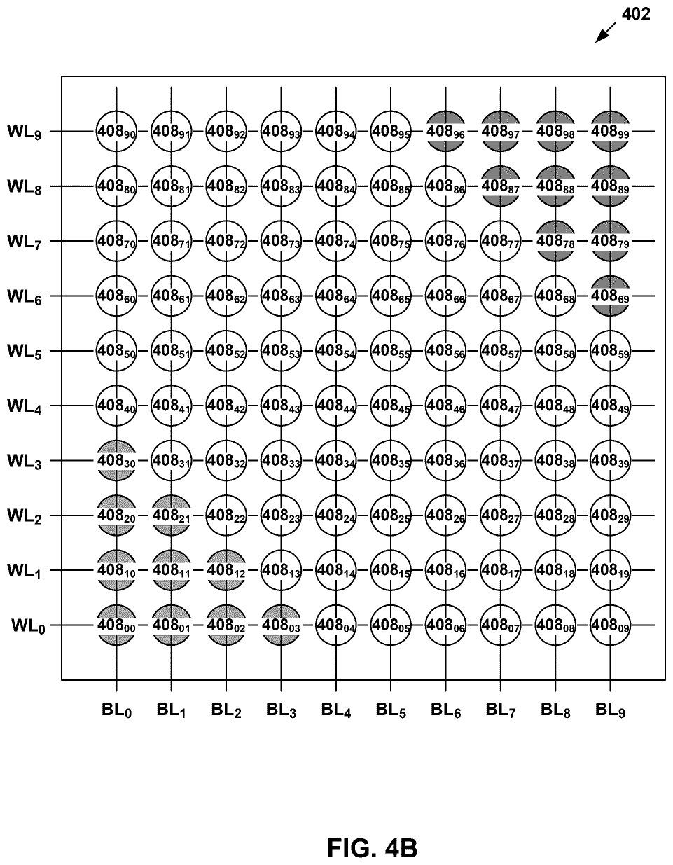

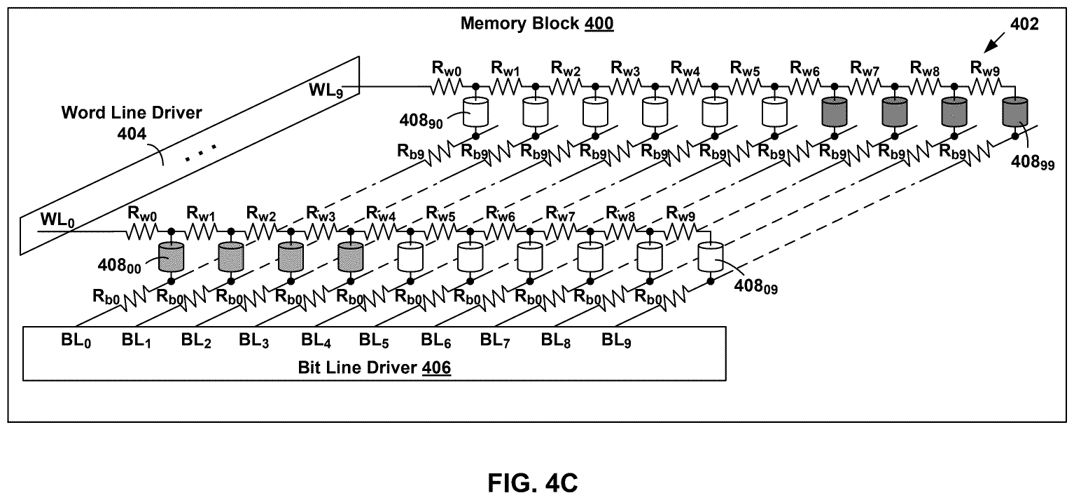

FIGS. 4A-4C are simplified diagrams of a memory block 400, which is an example of memory block 140 of FIG. 1E. Memory block 400 includes a memory array 402 coupled to a word line driver circuit 404 and a bit line driver circuit 406. Memory array 402 also includes word lines WL₀, WL₁, . . . , WL₉ coupled to word line driver circuit 404, and bit lines BL₀, BL₁, . . . , BL₉ coupled to bit line driver circuit 406. Persons of ordinary skill in the art will understand that memory array 402 may have more or fewer than 9 word lines and mor or fewer than 9 bit lines.

In an embodiment, memory cells 408_{xy} are disposed at the intersection of each of word lines WL₀, WL₁, . . . , WL₉ and bit lines BL₀, BL₁, . . . , BL₉ (with x=word line number and y=bit line number). In an embodiment, each memory cell 408_{xy} includes a selector element coupled in series with a resistance-switching memory element, such as example memory cells 222 of FIG. 2A. In an embodiment, each memory cell 408_{xy} includes a selector element coupled in series with a magnetic memory element, such as example memory cell 222a of FIG. 2B.

FIG. 4A is a top-level view of memory block 400, and FIG. 4B is a top-level view of memory array 402, depicting each memory cell 408_{xy} number. In FIG. 4A, includes numerical values depicted above each memory cell 408_{xy} represent total path lengths for each memory cell 408_{xy}. As used herein, a “total path length” is a sum of word line path lengths and bit line path lengths to the memory cell 408_{xy}. As used herein, a “word line path length” corresponds to a length of the corresponding word line from word line driver circuit 404 to the memory cell 408_{xy}, and a “bit line path length” corresponds to a length of the corresponding bit line from bit line driver circuit 406 to the memory cell 408_{xy}.

For example, memory cell 408₀₀ disposed at the intersection of word line WL₀ and bit line BL₀ is located one word line path length from word line driver circuit 404 and one bit line path length from bit line driver circuit 406, and thus the memory cell has a total path length of 2. Likewise, memory cell 408₁₅ disposed at the intersection of word line WL₁ and bit line BL₅ is located 6 word line path lengths from word line driver circuit 404 and two bit line path length from bit line driver circuit 406, and thus the memory cell has a total path length of 8.

Thus, the depicted total path lengths represent the relative proximity of each memory cell 408_{xy} to both word line driver circuit 404 and bit line driver circuit 406. Memory cells 408_{xy} coupled to bit lines BL₀, BL₁, . . . , BL₃ are relatively “near” word line driver circuit 404, and memory cells 408_{xy} coupled to word lines WL₀, WL₁, . . . , WL₃ are relatively “near” bit line driver circuit 406. In contrast, memory cells 408_{xy} coupled to bit lines BL₆, BL₇, . . . , BL₉ are relatively “far” from word line driver circuit 404, and memory cells 408_{xy} coupled to word lines WL₆, WL₇, . . . , WL₉ are relatively “far” from bit line driver circuit 406.

In an embodiment, memory cells 408_{xy} that are coupled to bit lines BL₀, BL₁, . . . , BL₃ and word lines WL₀, WL₁, . . . , WL₃ are referred to as “near-near” memory cells 408ₙₙ because the memory cells are located relatively “near” both word line driver circuit 404 and bit line driver circuit 406. In the example embodiment of FIGS. 4A-4C, near-near memory cells 408ₙₙ are shaded light gray, and include memory cells 408₀₀, 408₀₁, 408₀₂, 408₀₃, 408₁₀, 408₁₁, 408₁₂, 408₂₀, 408₂₁ and 408₃₀.

In an embodiment, memory cells 408_{xy} coupled to bit lines BL₆, BL₇, . . . , BL₉ and word lines WL₆, WL₇, . . . , WL₉ are referred to herein as “far-far” memory cells 408_{ff} because the memory cells are located relatively “far” from word line driver circuit 404 and bit line driver circuit 406. In the example embodiment of FIGS. 4A-4C, far-far memory cells 408_{ff} are shaded dark gray, and include memory cells 408₉₆, 408₉₇, 408₉₈, 408₉₉, 408₈₇, 408₈₈, 408₈₉, 408₇₈, 408₇₉ and 408₆₉.

Ideally, word lines WL₀, WL₁, . . . , WL₉ and bit lines BL₀, BL₁, . . . , BL₉ have zero resistance. In reality, however, word lines WL₀, WL₁, . . . , WL₉ and bit lines BL₀, BL₁, . . . , BL₉ each have a non-zero resistance that increases with increasing length. FIG. 4B depicts word line resistances R_{w0}, R_{w1}, . . . , R_{w9} for each of word lines WL₀, WL₁, . . . , WL₉, and bit line resistances R_{b0}, . . . , R_{b9} for each of bit lines BL₀, BL₁, . . . , BL₉. FIG. 4C depicts a simplified model of memory array 402 including word line resistances R_{w} and bit line resistances R_{b}.

For example, for word line WL₀, word line resistance R_{w0} represents the resistance of the word line path length from word line driver circuit 404 to memory cell 408₀₀, word line resistance R_{w1} represents the resistance of the word line path length from memory cell 408₀₀ to memory cell 408₀₁, and so on. For simplicity, word line resistances R_{w0}, R_{w1}, . . . , R_{w9} are assumed to be the same for each of word lines WL₀, WL₁, . . . , WL₉, which is accurate to a first order approximation. In addition, word line resistances R_{w0}, R_{w1}, . . . , R_{w9} are assumed to have the same value R.

Similarly, for bit line BL₀, bit line resistance R_{b0} represents the resistance of the bit line path length from bit line driver circuit 406 to memory cell 408₀₀, bit line resistance R_{b9} represents the resistance of the bit line path length from memory cell 408₈₀ to memory cell 408₉₀, and so on. For simplicity, bit line resistances R_{b0}, . . . , R_{b9} are assumed to be the same for each of bit lines BL₀, BL₁, . . . , BL₉, which is accurate to a first order approximation. In addition, bit line resistances R_{b0}, R_{b1}, . . . , R_{b9} are assumed to have the same value R.

In an embodiment, each of memory cells 408_{xy} has a corresponding “total path resistance” (TR_{xy}) which is a sum of the resistance of the corresponding word line from word line driver circuit 404 to the memory cell 408_{xy}, and the resistance of the corresponding bit line from the memory cell 408_{xy} to bit line driver circuit 406.

Thus, memory cell 408₀₀ has a corresponding total path resistance of TR₀₀=R_{w0}+R_{b0}=2×R, memory cell 408₀₁ has a corresponding total path resistance of TR₀₁=R_{w0}+R_{w1}+R_{b0}=3×R, memory cell 408₉₉ has a corresponding total path resistance of TR₉₉=R_{w0}+R_{w1}+ . . . +R_{w9}+R_{b0}+R_{b1}+ . . . +R_{b9}=20×R, and so on. Thus, the numerical values depicted above each memory cell 408_{xy} in FIG. 4A also represent the multiplier for the corresponding total path resistance TR_{xy} of each memory cell.

Thus, near-near memory cells 408ₙₙ have relatively short distances from word line driver circuit 404 and bit line driver circuit 406b, and have relatively small corresponding total path resistances TR_{xy}, and far-far memory cells 408_{ff} have relatively long distances from word line driver circuit 404 and bit line driver circuit 406b, and have relatively large corresponding total path resistances TR_{xy}.

In an embodiment, memory array 402 is divided into multiple zones: a first zone 410 (also referred to herein as a “near-near zone”) includes near-near memory cells 408ₙₙ having a lowest corresponding total path resistance TR_{xy}, a second zone 412 (also referred to herein as a “far-far zone”) includes far-far memory cells 408_{ff} having a highest corresponding total path resistance TR_{xy}, and a third zone 414 (also referred to herein as a “mid zone”) includes all memory cells 408_{xy} that are neither near-near or far-far memory cells. Persons of ordinary skill in the art will understand that memory array 402 may be divided into more or fewer than three zones.

In an embodiment, near-near memory cells 408ₙₙ have a corresponding total path resistance TR_{xy} that is less than a first (e.g., lower) threshold resistance R_{L}, and far-far memory cells 408_{ff} have a corresponding total path resistance TR_{xy} that is greater than a second (e.g., upper) threshold resistance R_{U}. For example, in the embodiment of FIGS. 4A-4C, lower threshold resistance R_{L}=6×R and upper threshold resistance R_{U}=16×R. Persons of ordinary skill in the art will understand that other values may be selected for upper threshold resistance R_{U} and lower threshold resistance R_{L}.

In the example embodiment of FIGS. 4A-4C, a difference in total path resistance TR_{xy} for near-near memory cells 408ₙₙ and far-far memory cells 408_{ff} ranges between a lower total path resistance difference Δ_{TPRL}=(17×R−5×R)=12×R and an upper total path resistance difference Δ_{TPRU}=(20×R−2×R)=18×R, and has an average total path resistance difference of Δ_{TPRA}=15×R. For simplicity, the remaining discussion will assume that near-near memory cells 408ₙₙ have a corresponding total path resistance TR_{xy} that is lower than that of far-far memory cells 408_{ff} by average total path resistance difference Δ_{TPRA}.

In some embodiments, average total path resistance difference Δ_{A} may be about 25 kΩ, and can have several negative effects on memory cells 408_{xy} that include a selector element (such as an ovonic threshold switch) coupled in series with a magnetic memory element, such as example memory cell 222a of FIG. 2B.

In particular, when an ovonic threshold switch turns ON, the voltage across ovonic threshold switch S_{X} drops to a relatively low value, and the remaining voltage drops across both the word line and the memory element Mₓ of the memory cell. This remaining voltage is referred to herein as a “snapback voltage.” Snapback may cause read-disturb in which the state of the memory element Mₓ can be inadvertently changed during reading.

For each memory cell 408_{xy}, the resistance of the memory cell and the corresponding total path resistance TR_{xy} of the memory cell act like a voltage divider. Thus, the lower the total path resistance TR_{xy}, the more snapback voltage drops across the corresponding memory cell 408_{xy}.

Thus, because near-near memory cells 408ₙₙ have corresponding total path resistances TR_{xy} that are lower than that of far-far memory cells 408_{ff} by average total path resistance difference Δ_{TPRA}, near-near memory cells 408ₙₙ tend to experience higher read disturb than far-far memory cells 408_{ff}. In addition to read disturb, the higher snapback voltage across near-near memory cells 408ₙₙ negatively impacts endurance of such memory cells compared to far-far memory cells 408_{ff}.

An additional problem caused by the average total path resistance difference Δ_{TPRA} between near-near memory cells 408ₙₙ and far-far memory cells 408_{ff} is that higher voltage levels must be used if word line driver circuit 404 and bit line driver circuit 406 use constant voltages for memory operations. In particular, because far-far memory cells 408_{ff} have higher corresponding total path resistance TR_{xy}, voltage drops on the lines require higher voltages at word line driver circuit 404 and bit line driver circuit 406 to achieve necessary voltage levels at far-far memory cells 408_{ff}. But as a result, near-near memory cells 408ₙₙ are subjected to higher voltages, further degrading endurance of near-near memory cells 408ₙₙ.

As an alternative to word line driver circuit 404 and bit line driver circuit 406 using constant voltages, CMOS voltage zoning techniques may be used to apply different voltages to memory cells 408_{xy} based on the zone in which the memory cells 408_{xy} are located. But such CMOS voltage zoning techniques require additional design and trimming complexity.

Also, leakage current is a problem for far-far memory cells 408_{ff}. If near-near memory cells 408ₙₙ had increased resistance, leakage current of far-far memory cells 408_{ff} may improve by reducing leakage current through near-near memory cells 408ₙₙ.

Technology is described to reduce average total path resistance difference Δ_{TPRA} between near-near memory cells and far-far memory cells. In embodiments, an additional resistance is added to near-near memory cells 408ₙₙ to effectively increase the corresponding total path resistance TR_{xy} of near-near memory cells 408ₙₙ. In embodiments, the added resistance has a value substantially equal to the average total path resistance difference Δ_{TPRA} between near-near memory cells 408ₙₙ and far-far memory cells 408_{ff}. Without wanting to be bound by any particular theory, it is believed that the added resistance may reduce a difference in total path resistance between near-near memory cells 408ₙₙ and far-far memory cells 408_{ff}.

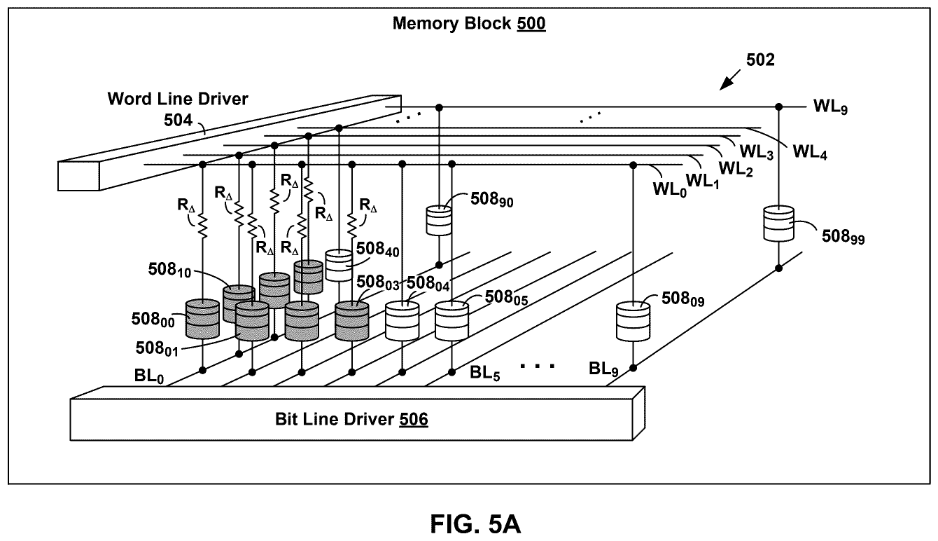

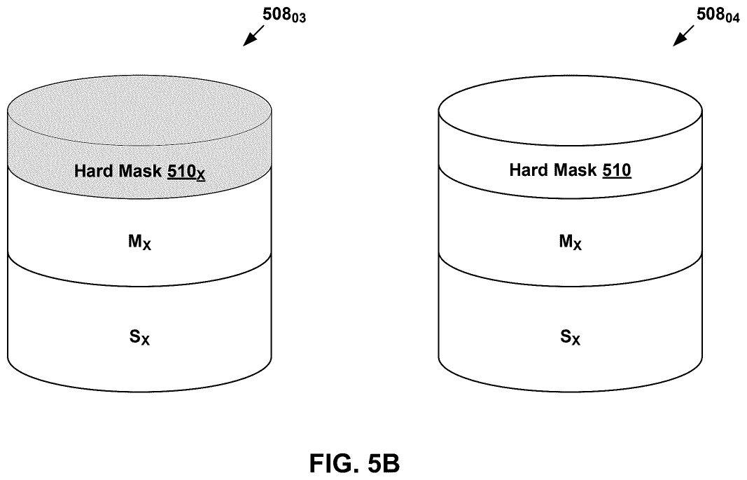

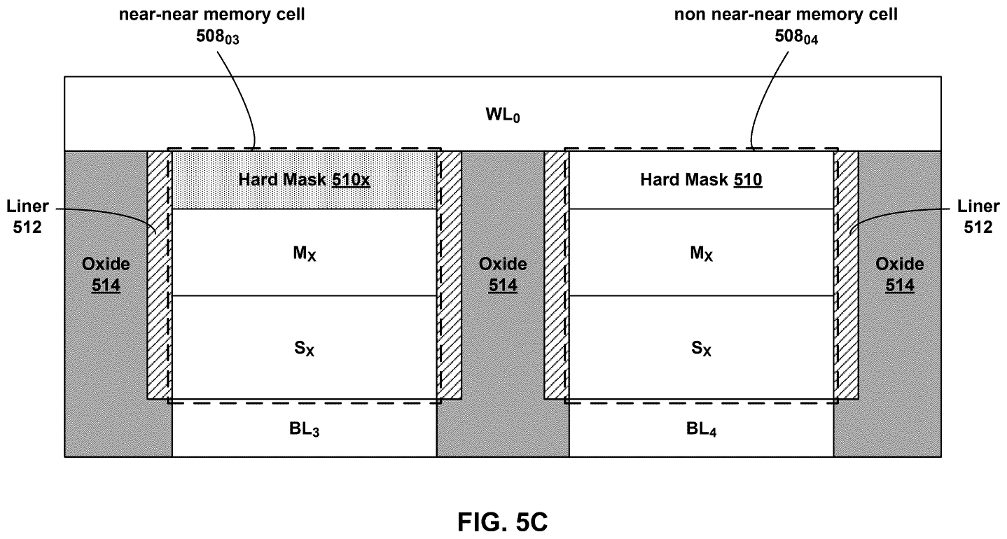

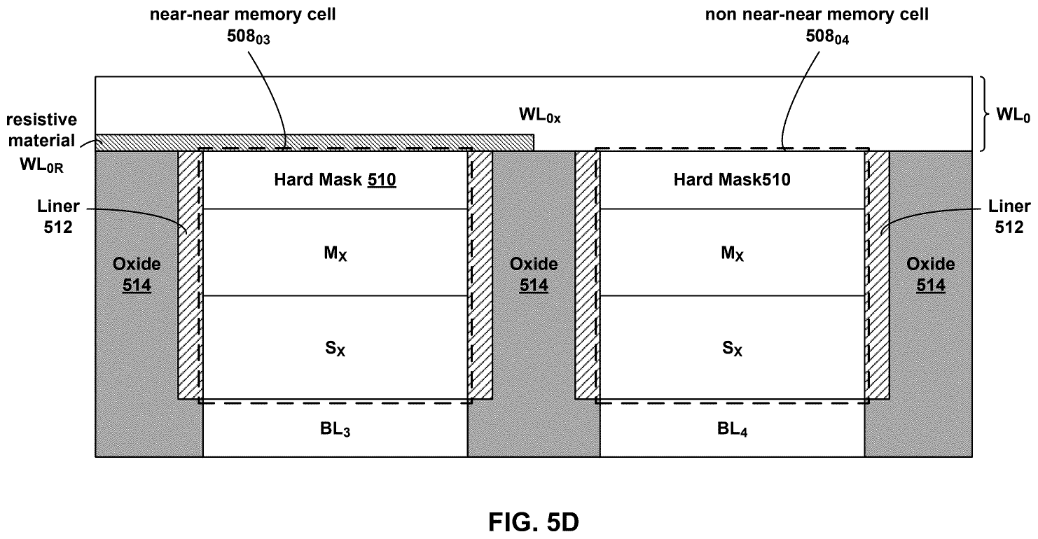

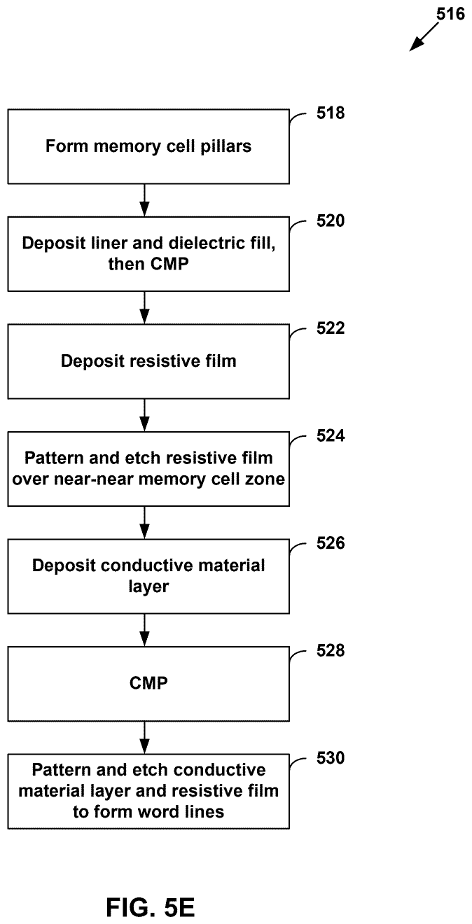

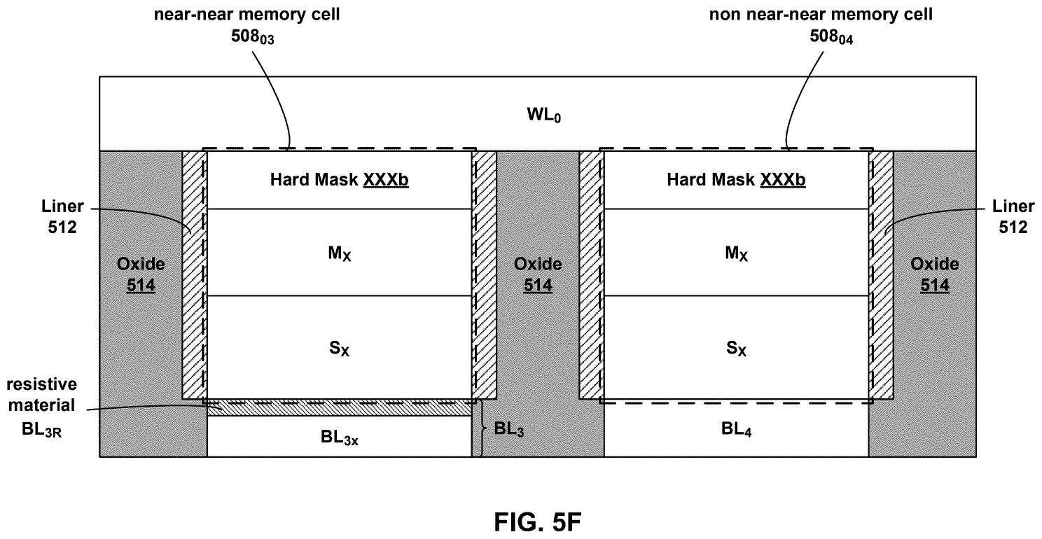

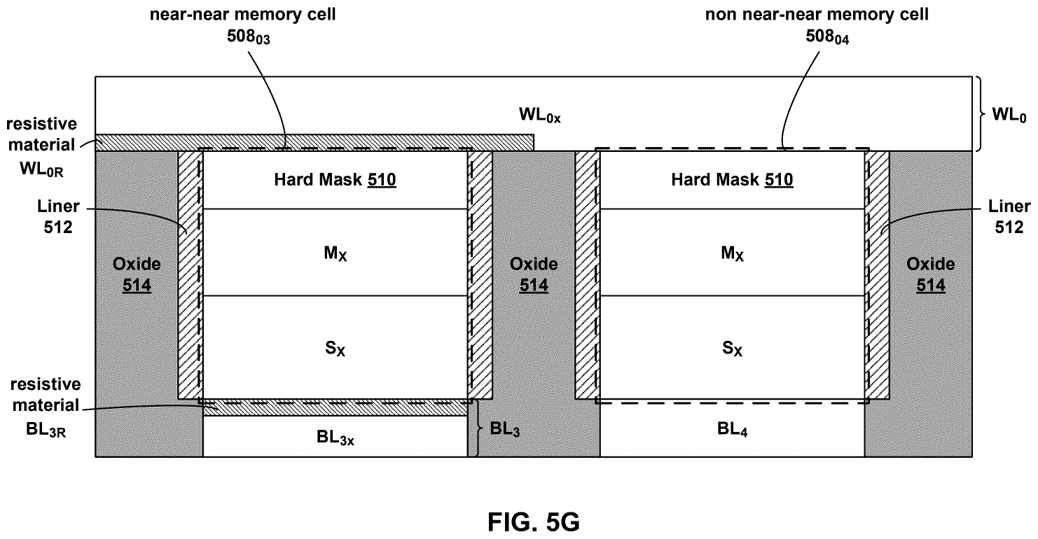

FIG. 5A is a simplified perspective view of a memory block 500, which is an example of memory block 140 of FIG. 1E. Memory block 500 includes a memory array 502 coupled to a word line driver circuit 504 and a bit line driver circuit 506. Memory array 502 also includes word lines WL₀, WL₁, . . . , WL₉ coupled to word line driver circuit 504, and bit lines BL₀, BL₁, . . . , BL₉ coupled to bit line driver circuit 506. Persons of ordinary skill in the art will understand that memory array 502 may have more or fewer than 9 word lines and mor or fewer than 9 bit lines.

In an embodiment, memory cells 508_{xy} are disposed at the intersection of each of word lines WL₀, WL₁, . . . , WL₉ and bit lines BL₀, BL₁, . . . , BL₉ (with x=word line number and y=bit line number). In an embodiment, each memory cell 508_{xy} includes a selector element coupled in series with a resistance-switching memory element, such as example memory cells 222 of FIG. 2A. In an embodiment, each memory cell 508_{xy} includes a selector element coupled in series with a magnetic memory element, such as example memory cell 222a of FIG. 2B.

In an embodiment, memory array 502 includes a first zone (e.g., a near-near zone) that includes near-near memory cells 508ₙₙ, a second zone (e.g., a far-far zone) that includes far-far memory cells 508_{ff}, and a third zone (e.g., a mid zone) that includes all other memory cells 508_{xy}, similar to near-near zone 410, far-far zone 412, and mid zone 414 of memory array 402 of FIG. 4A.

Thus, similar to memory array 402 of FIG. 4A, the near-near zone of memory array 502 include memory cells 508₀₀, 508₀₁, 508₀₂, 508₀₃, 508₁₀, 508₁₁, 508₁₂, 508₂₀, 508₂₁ and 508₃₀, and the far-far zone of memory array 502 include 508₉₆, 508₉₇, 508₉₈, 508₉₉, 508₈₇, 508₈₈, 508₈₉, 508₇₈, 508₇₉ and 508₆₉, some of which are depicted in FIG. 5A. Near-near memory cells 508ₙₙ are depicted shaded light gray, and all other memory cells 508_{xy} that are not near-near memory cells 508ₙₙ have no shading.

In an embodiment, an added resistance R_{Δ} is incorporated in and/or coupled to each near-near memory cell 508ₙₙ. In the example embodiment of FIG. 5A, added resistance R_{Δ} is depicted coupled between each near-near memory cell 508ₙₙ and the corresponding word line WL₀, WL₁, WL₂ or WL₃ coupled to the near-near memory cell 508ₙₙ. In some alternative embodiments, added resistance Ra is coupled between each near-near memory cell 508ₙₙ and the corresponding bit line BL₀, BL₁, BL₂ or BL₃ coupled to the near-near memory cell 508ₙₙ.

In still other alternative embodiments, added resistance R_{Δ} is divided into two parts, with a first part of added resistance R_{Δ} coupled between each near-near memory cell 508ₙₙ and the corresponding word line WL₀, WL₁, WL₂ or WL₃, and the second part of coupled between each near-near memory cell 508ₙₙ and the corresponding bit line BL₀, BL₁, BL₂ or BL₃ coupled to the near-near memory cell 508ₙₙ.

In an embodiment, each added resistance R_{Δ} has a value substantially equal to a total path resistance difference Δ_{TPR} between near-near memory cells 508ₙₙ and far-far memory cells 508_{ff}. In embodiments, total path resistance difference Δ_{TPR} may be any of an average, a median, a maximum, or a minimum or the total path resistance difference (e.g., determined empirically, via simulation, or a combination thereof) between near-near memory cells 508ₙₙ and far-far memory cells 508_{ff}.

In other embodiments, total path resistance difference Δ_{TPR} may be some other measure or estimate of total path resistance difference between near-near memory cells 508ₙₙ and far-far memory cells 508_{ff}. Without wanting to be bound by any particular theory, it is believed that added resistance R_{Δ} may reduce a difference in total path resistance TR_{xy} between near-near memory cells 508ₙₙ and far-far memory cells 508_{ff}.

In an embodiment, added resistance R_{Δ} is incorporated into each near-near memory cell 508ₙₙ by altering the structure of near-near memory cells 508ₙₙ compared with the structure of all other memory cells 508_{xy} in memory array 502. In an embodiment, each memory cell 508_{xy} in memory array 502 includes a magnetic memory element Mₓ coupled in series with a selector element Sₓ, such as example memory cell 222a of FIG. 2B.

In addition, although not depicted in FIG. 2B, each memory cell 222a also includes a hard mask layer disposed above magnetic memory element Mₓ. In embodiments, the hard mask layer is used during fabrication to form memory cell pillars each including magnetic memory element Mₓ and selector element Sₓ.

For example, FIG. 5B is a simplified perspective view of an embodiment of memory cells 508₀₃ and 508₀₄ of memory array 502. In this example, memory cell 508₀₃ is a near-near memory cell 508ₙₙ and memory cell 508₀₄ is not a near-near memory cell 508ₙₙ. Memory cells 508₀₃ and 508₀₄ each include a magnetic memory element Mₓ disposed above a selector element Sₓ. In addition, a hard mask is disposed above each magnetic memory element Mₓ.

In particular, memory cell 508₀₄ (and all other memory cells 508_{xy} that are not in the near-near zone of memory array 502) includes a first hard mask 510 disposed above magnetic memory element Mₓ, and memory cell 508₀₃ (and all other near-near memory cells 508ₙₙ in the near-near zone of memory array 502) includes a second hard mask 510_{X} disposed above magnetic memory element Mₓ.

In an embodiment, first hard mask 510 and second hard mask 510_{X} have substantially the same dimensions, but include different hard mask materials. In an embodiment, first hard mask 510 and second hard mask 510_{X} have substantially the same thickness (e.g., between about 10 nm to 100 nm, or other similar hard mask thickness).

In an embodiment, first hard mask 510 is fabricated from a first hard mask material layer, and second hard mask 510_{X} is fabricated from a second hard mask material layer. In an embodiment, the first hard mask material layer has a first resistivity, and the second hard mask material layer has a second resistivity higher than the first resistivity. In an embodiment, first hard mask 510 has a first resistance and second hard mask 510_{X} has a second resistance higher than the first resistance.

In an embodiment, a difference between the second resistance of second hard mask 510_{X} and the first resistance of first hard mask 510 is added resistance R_{Δ} that has a value substantially equal to a total path resistance difference Δ_{TPR} between near-near memory cells 508ₙₙ and far-far memory cells 508_{ff}.

In an embodiment, first hard mask 510 is fabricated from a first hard mask material that is formed using first processing parameters, and second hard mask 510_{X} is fabricated from a second hard mask material that is formed using second processing parameters different from first processing parameters. In embodiments, processing parameters include one or more of processing materials, times, temperatures, flow rates, and other similar processing parameters.

In embodiments, first hard mask 510 and second hard mask 510_{X} each are fabricated from metallic materials, such as on or more of tantalum (Ta), tantalum nitride (TaN), titanium (Ti), titanium nitride (TiN), tungsten (W), tungsten nitride WN), chromium (Cr), ruthenium (Ru) and other similar metallic materials. In some embodiments, first hard mask 510 and second hard mask 510_{X} are fabricated from the same metallic material, or from different metallic materials. In embodiments, the resistivity of metallic hard mask materials can be relatively well-controlled.

For example, Table 1, below depicts example thickness and resistivity of TaN film deposited with different sputtering times and nitrogen (N₂) flow rates:

TABLE 1
TaN Film Properties

| Sputtering | N₂ Flow | Thickness | Resistivity |
|---|---|---|---|
| time (min) | (sccm) | (nm) | (μΩ-cm) |
| 10 | 12 | 159.00 | 524.0 |
| 10 | 17 | 150.00 | 738.0 |
| 10 | 25 | 161.07 | 1,018.4 |
| 20 | 25 | 282.08 | 1,567.5 |
| 30 | 25 | 439.51 | 1,410.8 |
| 10 | 38 | 129.84 | 27,136.6 |
| 20 | 38 | 246.84 | 25,177.7 |
| 30 | 38 | 399.00 | 6.975.7 |
| 20 | 58 | 195.93 | 146,555.6 |

For example, for a 10 minute sputtering time, varying the N₂ flow rate from 12 sccm to 38 sccm, can cause the resistivity of the resulting TaN film to vary from 524.0μΩ-cm to 27,136.6 μΩ-cm. Persons of ordinary skill in the art will understand that the resistivity of other metallic hard mask materials may likewise be well controlled by process parameter control.

FIG. 5C is a simplified cross-sectional view during an example fabrication of memory cells 508₀₃ and 508₀₄ of memory array 502. In this example, near-near memory cell 508₀₃ is disposed between bit line BL₃ and word line WL₀, and memory cell 508₀₄ is disposed between bit line BL₄ and word line WL₀. In an embodiment, memory cells 508₀₃ and 508₀₄ are each surrounded by sidewall liners 512, and are separated from one another and from other memory cells 508_{xy} by a dielectric material (e.g., silicon dioxide) 514.

In an embodiment, (non-near-near) memory cell 508₀₄ includes first hard mask 510 and near-near memory cell 508₀₃ includes second hard mask 510_{X} different from first hard mask 510. In an embodiment, first hard mask 510 has a first resistance and second hard mask 510_{X} has a second resistance. In embodiments, an additional photolithography step is used to form first hard mask 510 from a first hard mask material, and second hard mask 510ₓ from a second hard mask material different from the first hard mask material.

In an embodiment, a difference between the second resistance of second hard mask 510_{X} and the first resistance of first hard mask 510 is added resistance R_{Δ} that has a value substantially equal to a total path resistance difference Δ_{TPR} between near-near memory cells 508ₙₙ and far-far memory cells 508_{ff}. Without wanting to be bound by any particular theory, it is believed that added resistance R_{Δ} may reduce a difference in total path resistance TR_{xy} between near-near memory cells 508ₙₙ and far-far memory cells 508_{ff}.

As described above and as depicted in FIGS. 5B-5C, in an embodiment added resistance Ra may be incorporated in each near-near memory cell 508ₙₙ by altering the structure of near-near memory cells 508ₙₙ in the near-near zone compared with the structure of all other memory cells 508_{xy} that are not located in the near-near zone in memory array 502.

In other embodiments, all memory cells 508_{xy} in memory array 502 may have the same structure, but added resistance R_{Δ} may be incorporated by including an additional resistance material layer in portions of the word lines and/or bit lines that are coupled to near-near memory cells 508ₙₙ in the near-near zone of memory array 502.

For example, FIG. 5D is a simplified cross-sectional view during an alternative example fabrication of memory cells 508₀₃ and 508₀₄ of memory array 502. As in the embodiment of FIG. 5C, near-near memory cell 508₀₃ is disposed between bit line BL₃ and word line WL₀, and memory cell 508₀₄ is disposed between bit line BL₄ and word line WL₀. In the embodiment of FIG. 5D, however, near-near memory cell 508₀₃ and (non-near-near) memory cell 508₀₄ each include first hard mask 510 having substantially the same resistance.

In the embodiment of FIG. 5D, word line WL₀ includes a first word line portion WL_{0X} and a second word line portion WL_{0R} disposed between near-near memory cells 508ₙₙ and first word line portion WL_{0X}. In an embodiment, the first word line portion WL_{0X} has a first resistivity, and the second word line portion WL_{0R} has a second resistivity higher than the first resistivity. In an embodiment, second word line portion WL_{0R} includes a resistive material (e.g., TaN, TiN or other similar material).

In embodiments, the region of second word line portions (such as second word line portion WL_{0R}) disposed above each near-near memory cell 508ₙₙ (such as near-near memory cell 508₀₃) constitutes added resistance R_{Δ} that has a value substantially equal to a total path resistance difference Δ_{TPR} between near-near memory cells 508ₙₙ and far-far memory cells 508_{ff}. Without wanting to be bound by any particular theory, it is believed that added resistance R_{Δ} may reduce a difference in total path resistance TR_{xy} between near-near memory cells 508ₙₙ and far-far memory cells 508_{ff}.

FIG. 5E is a flow diagram of a simplified process 516 for forming a memory array such as the portion of memory array 502 depicted in FIG. 5D.

At step 518, form memory cell pillars that each include a magnetic memory element Mₓ disposed above a selector element Sₓ. In an embodiment, each memory cell pillar also includes a hard mask 510 disposed above magnetic memory element Mₓ.

At step 520, deposit liner and dielectric fill, the perform chemical mechanical polishing (CMP) to expose the hard mask tops of the pillars.

At step 522, deposit a resistive film that will form second word line portions WL_{0R}. In embodiments, the resistive film may be TiN, TaN, or other similar material. In embodiments, the resistive film may be between about 2 nm and about 15 nm, although other thicknesses may be used.

At step 524, pattern and etch the deposited resistive film over the near-near memory cell zone.

At step 526, deposit a conductive material layer (e.g., W) that will form word lines. In embodiments, the deposited conductive film may be between about 40 nm and 60 nm, although other thicknesses may be used.

At step 528, CMP the blanket conductive material layer to erase any steps over the resistive film.

At step 530, pattern and etch the conductive material layer and added resistive film to form the word lines.

In the embodiment of FIG. 5D, added resistance R_{Δ} is incorporated by including an additional resistance material layer in portions of the word lines coupled to near-near memory cells 508ₙₙ. In other embodiments, added resistance R_{Δ} is incorporated by including an additional resistance material layer in portions of the bit lines coupled to near-near memory cells 508ₙₙ.

For example, FIG. 5F is a simplified cross-sectional view during another alternative example fabrication of memory cells 508₀₃ and 508₀₄ of memory array 502. As in the embodiment of FIG. 5D, near-near memory cell 508₀₃ is disposed between bit line BL₃ and word line WL₀, and memory cell 508₀₄ is disposed between bit line BL₄ and word line WL₀, and near-near memory cell 508₀₃ and (non near-near) memory cell 508₀₄ each include first hard mask 510 having substantially the same resistance.

In the embodiment of FIG. 5F, however, bit line BL₃ includes a first bit line portion BL_{3X} and a second bit line portion BL_{3R} disposed between near-near memory cell 508₀₃ and first bit line portion BL_{03X}. In an embodiment, the first bit line portion BL_{3X} has a first resistivity, and the second bit line portion WL_{3R} has a second resistivity higher than the first resistivity. In an embodiment, second bit line portion BL_{3R} includes a resistive material (e.g., TaN, TiN or other similar material).

In embodiments, the region of second bit line portions (such as second bit line portion BL_{3R}) disposed below each near-near memory cell 508ₙₙ (such as near-near memory cell 508₀₃) constitutes added resistance R_{Δ} that has a value substantially equal to a total path resistance difference Δ_{TPR} between near-near memory cells 508ₙₙ and far-far memory cells 508_{ff}. Without wanting to be bound by any particular theory, it is believed that added resistance R_{Δ} may reduce a difference in total path resistance TR_{xy} between near-near memory cells 508ₙₙ and far-far memory cells 508_{ff}.

In the embodiment of FIG. 5D, added resistance Ra is incorporated by including an additional resistance material layer in portions of the word lines coupled to near-near memory cells 508ₙₙ, and in the embodiment of FIG. 5F added resistance R_{Δ} is incorporated by including an additional resistance material layer in portions of the bit lines coupled to near-near memory cells 508ₙₙ. In another alternative embodiment, these techniques may be combined to incorporate added resistance Ra to near-near memory cells 508ₙₙ

In particular, FIG. 5G is a simplified cross-sectional view during yet another alternative example fabrication of memory cells 508₀₃ and 508₀₄ of memory array 502. As in the embodiments of FIGS. 5D and 5F, near-near memory cell 508₀₃ is disposed between bit line BL₃ and word line WL₀, and memory cell 508₀₄ is disposed between bit line BL₄ and word line WL₀, and near-near memory cell 508₀₃ and (non near-near) memory cell 508₀₄ each include first hard mask 510 having substantially the same resistance.

In the embodiment of FIG. 5G, however, word line WL₀ includes a first word line portion WL_{0X} and a second word line portion WL_{0R} disposed between near-near memory cells 508ₙₙ and first word line portion WL_{0X}. In addition, bit line BL₃ includes a first bit line portion BL_{3X} and a second bit line portion BL_{3R} disposed between near-near memory cell 508₀₃ and first bit line portion BL_{03X}.

In an embodiment, the first word line portion WL_{0X} has a first resistivity, and the second word line portion WL_{0R} has a second resistivity higher than the first resistivity. In an embodiment, the first bit line portion BL_{3X} has a third resistivity, and the second bit line portion BL_{3R} has a fourth resistivity higher than the third resistivity. In an embodiment, second word line portion WL_{0R} and second bit line portion BL_{3R} include a resistive material (e.g., TaN, TiN or other similar material).

In embodiments, the region of second word line portions (such as second word line portion WL_{0R}) disposed above each near-near memory cell 508ₙₙ (such as near-near memory cell 508₀₃) and the region of second bit line portions (such as second bit line portion BL_{3R}) disposed below each near-near memory cell 508ₙₙ (such as near-near memory cell 508₀₃) collectively constitute added resistance R_{Δ} that has a value substantially equal to a total path resistance difference Δ_{TPR} between near-near memory cells 508ₙₙ and far-far memory cells 508_{ff}. Without wanting to be bound by any particular theory, it is believed that added resistance R_{Δ} may reduce a difference in total path resistance TR_{xy} between near-near memory cells 508ₙₙ and far-far memory cells 508_{ff}.

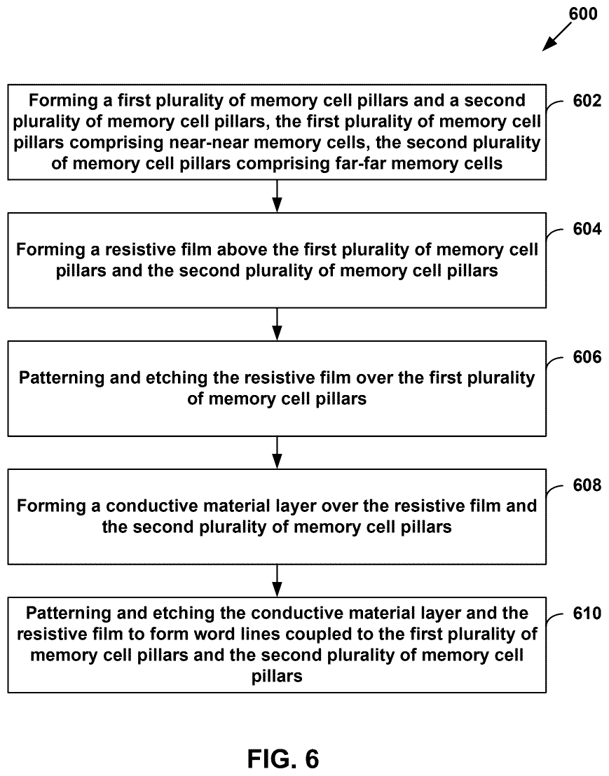

FIG. 6 depicts a flow diagram of an embodiment of a method 600 for forming a memory array, such as memory array 502 of FIG. 5A.

At step 602, forming a first plurality of memory cell pillars and a second plurality of memory cell pillars, the first plurality of memory cell pillars comprising near-near memory cells, the second plurality of memory cell pillars comprising far-far memory cells.

At step 604, forming a resistive film above the first plurality of memory cell pillars and the second plurality of memory cell pillars.

At step 606, patterning and etching the resistive film over the first plurality of memory cell pillars.

At step 608, forming a conductive material layer over the resistive film and the second plurality of memory cell pillars.

At step 610, patterning and etching the conductive material layer and the resistive film to form word lines coupled to the first plurality of memory cell pillars and the second plurality of memory cell pillars.

Without wanting to be bound by any particular theory, it is believed that the resistive film may compensate for a resistance difference between far-far memory cells and near-near memory cells.

One embodiment of the disclosed technology includes an apparatus that includes a first memory cell and a second memory cell. The first memory cell is coupled between a first word line and a first bit line and coupled in series with a first word line resistance and a first bit line resistance. The first memory cell includes a first hard mask including a first hard mask material. The second memory cell is coupled between a second word line and a second bit line and coupled in series with a second word line resistance and a second bit line resistance. The second memory cell includes a second hard mask including a second hard mask material. The first hard mask material has a first resistivity, and the second hard mask material has a second resistivity lower than the first resistivity. The first hard mask is configured to compensate for a difference between a first sum of the first word line resistance and the first bit line resistance and a second sum of the second word line resistance and the second bit line resistance.

One embodiment of the disclosed technology includes an apparatus that includes a first word line including a first word line portion including a first resistivity, and a second word line portion including a second resistivity higher than the first resistivity, a first memory cell coupled between the first word line and a first bit line, the first word line including a first word line resistance and the first bit line including a first bit line resistance, and a second memory cell coupled between a second word line and a second bit line, the second word line including a second word line resistance, and the second bit line including a second bit line resistance. The second word line portion of the first word line is disposed between the first memory cell and the first word line portion of the first word line. The second word line portion is configured to compensate for a difference between a first sum of the first word line resistance and the first bit line resistance and a second sum of the second word line resistance and the second bit line resistance.

One embodiment of the disclosed technology includes a method that includes forming a first plurality of memory cell pillars and a second plurality of memory cell pillars, the first plurality of memory cell pillars including near-near memory cells, the second plurality of memory cell pillars including far-far memory cells, forming a resistive film above the first plurality of memory cell pillars and the second plurality of memory cell pillars, patterning and etching the resistive film over the first plurality of memory cell pillars, forming a conductive material layer over the resistive film and the second plurality of memory cell pillars, and patterning and etching the conductive material layer and the resistive film to form word lines coupled to the first plurality of memory cell pillars and the second plurality of memory cell pillars. The resistive film is configured to compensate for a resistance difference between far-far memory cells and near-near memory cells.

For purposes of this document, a first layer may be over or above a second layer if zero, one, or more intervening layers are between the first layer and the second layer.

For purposes of this document, it should be noted that the dimensions of the various features depicted in the figures may not necessarily be drawn to scale.

For purposes of this document, reference in the specification to “an embodiment,” “one embodiment,” “some embodiments,” or “another embodiment” may be used to describe different embodiments and do not necessarily refer to the same embodiment.

For purposes of this document, a connection may be a direct connection or an indirect connection (e.g., via another part). In some cases, when an element is referred to as being connected or coupled to another element, the element may be directly connected to the other element or indirectly connected to the other element via intervening elements. When an element is referred to as being directly connected to another element, then there are no intervening elements between the element and the other element.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An apparatus comprising:
a first memory cell coupled between a first word line and a first bit line and coupled in series with a first word line resistance and a first bit line resistance, the first memory cell comprising a first hard mask comprising a first hard mask material; and
a second memory cell coupled between a second word line and a second bit line and coupled in series with a second word line resistance and a second bit line resistance, the second memory cell comprising a second hard mask comprising a second hard mask material,
wherein:
the first hard mask material has a first resistivity, and the second hard mask material has a second resistivity lower than the first resistivity; and
the first hard mask is configured to compensate for a difference between a first sum of the first word line resistance and the first bit line resistance and a second sum of the second word line resistance and the second bit line resistance.

2. The apparatus of claim 1, wherein:
the first sum is less than a first threshold resistance; and
the second sum is greater than a second threshold resistance.

3. The apparatus of claim 1, wherein the first hard mask has a first resistance and the second hard mask has a second resistance lower than the first resistance.

4. The apparatus of claim 3, wherein a difference between the first resistance and the second resistance substantially equals the difference between the second sum and the first sum.

5. The apparatus of claim 1, wherein the first hard mask material is formed using first processing parameters, and the second hard mask material is formed using second processing parameters different from first processing parameters.

6. The apparatus of claim 5, wherein the first processing parameters and the second processing parameters each include one or more of processing materials, times, temperatures, and flow rates.

7. The apparatus of claim 1, wherein the first hard mask and the second hard mask each comprise a metallic material.

8. The apparatus of claim 1, wherein the first hard mask and the second hard mask each comprise one or more of tantalum, tantalum nitride, titanium, titanium nitride, tungsten, tungsten nitride, chromium, and ruthenium.

9. The apparatus of claim 1, wherein the first hard mask material and the second hard mask material comprise a same material.

10. The apparatus of claim 1, wherein the first hard mask material and the second hard mask material comprise different materials.

11. The apparatus of claim 1, wherein the first memory cell and the second memory cell each comprise a magnetic memory element coupled in series with a selector element.

12. The apparatus of claim 1, wherein the first memory cell comprises a near-near memory cell and the second memory cell comprises a far-far memory cell.

13. An apparatus comprising:
a first word line comprising a first word line portion comprising a first resistivity, and a second word line portion comprising a second resistivity higher than the first resistivity;
a first memory cell coupled between the first word line and a first bit line, the first word line comprising a first word line resistance and the first bit line comprising a first bit line resistance; and
a second memory cell coupled between a second word line and a second bit line, the second word line comprising a second word line resistance, and the second bit line comprising a second bit line resistance,
wherein:
the second word line portion of the first word line is disposed between the first memory cell and the first word line portion of the first word line;
the second word line portion is configured to compensate for a difference between a first sum of the first word line resistance and the first bit line resistance and a second sum of the second word line resistance and the second bit line resistance.

14. The apparatus of claim 13, wherein:
the first sum is less than a first threshold resistance; and
the second sum is greater than a second threshold resistance.

15. The apparatus of claim 13, wherein:
the first memory cell comprises a first hard mask comprising a first resistance; and
the second memory cell comprises a second hard mask comprising a second resistance substantially equal to the first resistance.

16. The apparatus of claim 13, wherein:
the first bit line comprises a first bit line portion comprising a third resistivity, and a second bit line portion comprising a fourth resistivity higher than the third resistivity;
the second bit line portion of the first bit line is disposed between the first memory cell and the first bit line portion of the first bit line;
the second bit line portion is configured to compensate for the difference between the first sum and the second sum.

17. The apparatus of claim 13, wherein the second word line portion and the second bit line portion are configured to compensate for the difference between the first sum and the second sum.

18. The apparatus of claim 13, wherein the first memory cell and the second memory cell each comprise a magnetic memory element coupled in series with a selector element.

19. A method comprising:
forming a first plurality of memory cell pillars and a second plurality of memory cell pillars, the first plurality of memory cell pillars comprising near-near memory cells, the second plurality of memory cell pillars comprising far-far memory cells;
forming a resistive film above the first plurality of memory cell pillars and the second plurality of memory cell pillars;
patterning and etching the resistive film over the first plurality of memory cell pillars;
forming a conductive material layer over the resistive film and the second plurality of memory cell pillars; and
patterning and etching the conductive material layer and the resistive film to form word lines coupled to the first plurality of memory cell pillars and the second plurality of memory cell pillars,
wherein the resistive film is configured to compensate for a resistance difference between far-far memory cells and near-near memory cells.

20. The method of claim 19, wherein the first plurality of memory cell pillars and a the second plurality of memory cell pillars each comprise a magnetic memory element coupled in series with a selector element.
